(19) United States
(12) Patent Application Publication
(10) Pub. No.: US 2026/0324067 A1
(43) Pub. Date: Oct. 15, 2026

(54) CFET DEVICE WITH GAA TRANSISTORS

(71) Applicant: Commissariat à I'Énergie Atomique et aux Énergies Alternatives, Paris (FR)

(72) Inventors: Fabien Roze, Grenoble (FR); Sylvain Barraud, Grenoble (FR)

(73) Assignee: Commissariat à I'Énergie Atomique et aux Énergies Alternatives, Paris (FR)

(21) Appl. No.: 19/641,398

(22) Filed: Apr. 7, 2026

(30) Foreign Application Priority Data
Apr. 11, 2025 (FR) FR2503906

(51) Int. Cl. H10D 84/85; H10D 84/01; H10D 84/02

(52) U.S. Cl. CPC H10D 84/856; H10D 84/0167; H10D 84/017; H10D 84/02; H10D 84/851

(57) ABSTRACT

Complementary field-effect transistor device (100), comprising:
a first transistor (192) of a first conductivity type comprising a first channel (140), first source/drain regions (156), and a first gate (164);
a second transistor (194) of a second conductivity type comprising a second channel (146), second source/drain regions (174), and a second gate (186);
a first dielectric portion (144) arranged between the first and second gates;
second dielectric portions (154), distinct from the first dielectric portion, each arranged between one of the first source/drain regions and one of the second source/drain regions;
and wherein side flanks of the first gate are aligned with side flanks of the second gate.

### TECHNICAL FIELD

The present disclosure generally concerns the fields of microelectronics and of semiconductor devices used, for example, for the manufacturing of logic computing components. The present disclosure more particularly concerns the field of devices with transistors of CFET (Complementary Field-Effect Transistor) type.

### PRIOR ART

A device with CFET transistors comprises N-type and P-type FETs (Field-Effect Transistors) stacked one above the other, or on top of one another, and having their channels formed by stacked semiconductor portions, for example in the form of nanosheets. The gates of these transistors may surround the channels similarly to transistors of GAA (“Gate-All-Around”) type.

In such a device, it is advantageous to have independent access to the transistor electrodes on the front and back sides of the device, in particular to optimize the density and the versatility of circuits incorporating this type of device. Nevertheless, existing devices and the methods implemented for their manufacturing have at least one of the following disadvantages: the structure of the device does not allow for distinct or non-shared gates between the upper and lower transistors; the gates of the upper and lower transistors are not aligned with one another; the structure of the device does not allow for gates surrounding the channels in a way similar to GAA-type transistors; the parasitic capacitances obtained in such devices, between the elements of the upper transistors and those of the lower transistors, are too high.

### SUMMARY OF THE INVENTION

There exists a need to provide a device with CFET transistors, as well as a method of manufacturing such a device, which does not exhibit at least part of the above-mentioned disadvantages.

An embodiment overcomes all or part of the disadvantages of known solutions and provides a device with complementary field-effect transistors, comprising at least:
a first transistor of a first conductivity type comprising a first channel, first source or drain regions, and a first gate arranged around the first channel;
a second transistor of a second conductivity type, opposite to the first conductivity type, comprising a second channel, second source or drain regions, and a second gate arranged around the second channel;
a first dielectric portion arranged between the first and second gates and configured to electrically insulate the first and second gates from each other;
second dielectric portions, distinct from the first dielectric portion, each arranged between one of the first source or drain regions and one of the second source or drain regions and configured to electrically insulate these first
and second source or drain regions from each other; and wherein side flanks of the first gate are aligned with side flanks of the second gate.

According to a specific embodiment, the first dielectric portion comprises at least one material having a chemical composition different from that of at least one material of each of the second dielectric portions.

According to a specific embodiment, the first and second dielectric portions each comprise at least one low-permittivity dielectric material.

According to a specific embodiment:
the first channel comprises at least one first nanosheet of at least one semiconductor having a crystallographic orientation different from that of at least one semiconductor of at least one second nanosheet of the second channel, or
the first channel and the first source or drain regions comprise at least one first layer of 2D material and/or semiconductor oxide, and the second channel and the second source or drain regions comprise at least one second layer of 2D material and/or semiconductor oxide.

According to a specific embodiment, the first gate comprises at least one first metal having a work function value different from that of at least one second metal of the second gate.

A method of manufacturing a device with complementary field-effect transistors is also provided, comprising at least:
forming a first transistor of a first conductivity type comprising a first channel, first source or drain regions, and a first gate arranged around the first channel;
forming a second transistor of a second conductivity type, opposite to the first conductivity type, comprising a second channel, second source or drain regions, and a second gate arranged around the second channel;
forming a first dielectric portion arranged between the first and second gates and configured to electrically insulate the first and second gates from each other;
forming second dielectric portions, distinct from the first dielectric portion, each arranged between one of the first source or drain regions and one of the second source or drain regions and configured to electrically insulate these first and second source or drain regions from each other; and wherein the first and second gates are formed in such a way that side flanks of the first gate are aligned with side flanks of the second gate.

According to a specific embodiment, the steps implemented for the forming of the first and second gates comprise a photolithography defining the alignment of the side flanks of the first gate with the side flanks of the second gate.

According to a specific embodiment, the forming of the first and second transistors and of the first and second dielectric portions comprises at least:
forming, on a first surface of the substrate, a structure comprising at least first and second semiconductor nanosheets intended to respectively form the first and second channels, in such a way that the second nanosheet is arranged between the first nanosheet and the substrate, the first dielectric portion arranged between the first and second nanosheets, and a dummy gate arranged around a portion of at least one assembly comprising at least the first and second nanosheets and the first dielectric portion;
etching, through a first part of the thickness of the substrate and from the first surface of the substrate, portions of the substrate not covered by the structure;
forming the second dielectric portions covering at least side flanks of the second nanosheet and of the first dielectric portion;
forming the first source or drain regions from side flanks of the first nanosheet;
removing at least a portion of the dummy gate, and forming the first gate;
etching a second part of the substrate thickness from a second surface of the substrate opposite to the first surface, so that at least a remaining portion of the substrate is arranged against the structure;
forming the second source or drain regions from side flanks of the second nanosheet;
removing the remaining portion of the substrate, and forming the second gate in self-aligned manner relative to the first gate.

According to a specific embodiment, the forming of the structure comprises at least:
forming, on the substrate, a stack comprising at least first and second semiconductor layers such that the second semiconductor layer is arranged between the first semiconductor layer and the substrate, and a dielectric layer arranged between the first and second semiconductor layers;
etching the stack so that at least a remaining portion of the stack forms a fin;
depositing at least one dummy gate material on top of and around the fin;
etching the dummy gate material and the fin, thereby forming the structure.

According to a specific embodiment, the forming of the stack comprises a bonding of a first portion of the dielectric layer previously formed on the first semiconductor layer to a second portion of the dielectric layer previously formed on the second semiconductor layer, which is arranged on the substrate.

According to a specific embodiment, the method further comprises, between the forming of the first source or drain regions and the removal of said at least one dummy gate portion, a deposition of a first sacrificial material covering the first source or drain regions.

According to a specific embodiment, the method further comprises, between the forming of the second source or drain regions and the removal of the remaining portion of the substrate, a deposition of a second sacrificial material covering the second source or drain regions.

According to a specific embodiment:
the first source or drain regions and the first gate are formed before the etching the second part of the substrate thickness, and the second source or drain regions and the second gate are formed after the etching of the second part of the substrate thickness, or
the first and second source or drain regions and the first gate are formed before the etching of the second part of the substrate thickness, and the second gate is formed after the etching of the second part of the substrate thickness.

According to a specific embodiment, when the first and second source or drain regions and the first gate are formed before the etching of the second part of the substrate thickness, the second source drain regions are formed before the first source or drain regions, which are protected by a sacrificial material deposited prior to the forming of the second source or drain regions.

According to a specific embodiment, the first gate is formed after the first and second source or drain regions, or the first gate is formed before the first and second source or drain regions.

According to a specific embodiment, the first and second transistors and the first and second dielectric portions comprise at least:
forming, on a first surface of the substrate, of a structure comprising at least first and second stacks, each comprising portions of first and second materials that can be etched selectively relative to one another and arranged in alternated fashion one above the others, such that the second stack is arranged between the first stack and the substrate, the structure also comprising the first dielectric portion arranged between the first and second stacks, and a dummy gate arranged around a portion of at least one assembly comprising at least the first and second stacks and the first dielectric portion;
etching, through a first part of the thickness of the substrate and from the first surface of the substrate, of portions of the substrate not covered by the structure;
forming of the second dielectric portions covering at least side flanks of the second stack and of the first dielectric portion;
etching of at least a portion of the dummy gate and of the portions of the first material of the first stack, followed by a forming of the first gate, and etching of portions of the second material of the first stack, followed by a deposition of at least one first layer of 2D material and/or semiconductor oxide forming the first channel and the first source or drain regions;
removal of a second part of the substrate thickness from a second surface of the substrate opposite to the first surface, such that at least a remaining portion of the substrate is arranged against the structure;
etching of the remaining portion of the substrate and of the portions of the first material of the second stack, followed by a forming of the second gate in self-aligned manner relative to the first gate, and etching of the portions of the second material of the second stack, followed by a deposition of at least one second layer of 2D material and/or semiconductor oxide forming the second channel and the second source or drain regions.

According to a specific embodiment:
the substrate is of semiconductor-on-insulator type and comprises a buried dielectric layer arranged between a support layer and a surface semiconductor layer, and
the thickness of the buried dielectric layer is equal to the first part of the substrate thickness, and
the remaining portion of the substrate corresponds to a portion of the buried dielectric layer.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1, FIG. 2, FIG. 3, FIG. 4, FIG. 5, FIG. 6, FIG. 7, FIG. 8, FIG. 9, FIG. 10, FIG. 11, FIG. 12, FIG. 13, FIG. 14, FIG. 15, FIG. 16, FIG. 17, FIG. 18, FIG. 19, FIG. 20, FIG. 21, FIG. 22, FIG. 23, FIG. 24, FIG. 25, FIG. 26, and FIG. 27 show steps of a method of manufacturing a device with CFET transistors according to a specific embodiment;

FIG. 28, FIG. 29, and FIG. 30 show part of the steps of a method of manufacturing a device with CFET transistors according to another specific embodiment;

FIG. 31 shows a device with CFET transistors according to another specific embodiment.

### DESCRIPTION OF THE EMBODIMENTS

The same elements have been designated by the same references in the various figures. In particular, structural and/or functional elements common to the different embodiments may have the same references and may have identical structural, dimensional and material properties. In the figures, to make their reading easier, the various elements and the various layers of materials are not shown to the same scale relative to one another.

For the sake of clarity, only those steps and elements that are useful for understanding the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

Throughout the document, the terms “conductive” and “insulating” are used to respectively designate an electrical conduction and an electrical insulation.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings in a normal position of use. However, these terms do not presume the real position and orientation of the device during its use.

Unless specified otherwise, the expressions “about”, “approximately”, “substantially”, and “in the order of” signify plus or minus 10%, preferably of plus or minus 5%.

Similarly, unless otherwise indicated, the indicated ranges of values include the limits of those ranges.

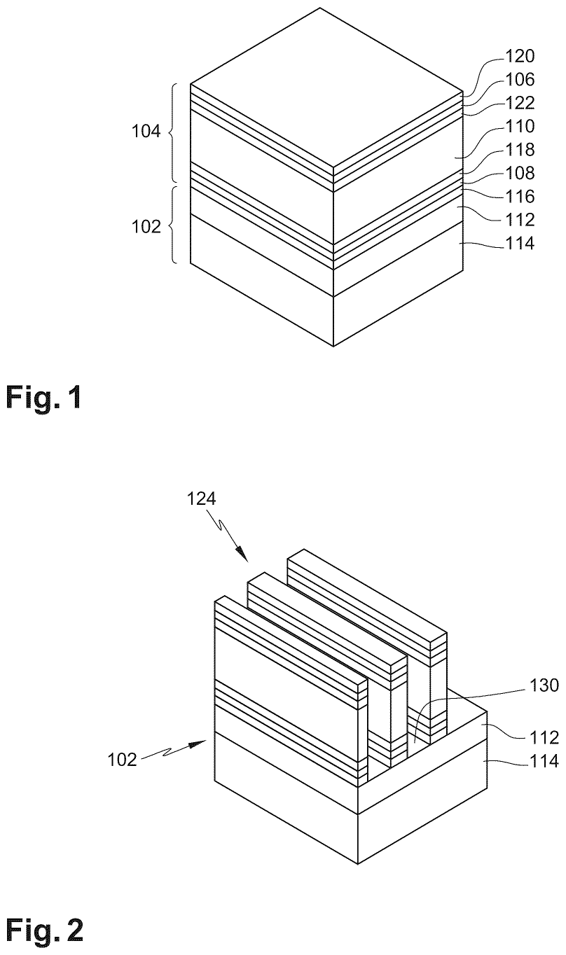

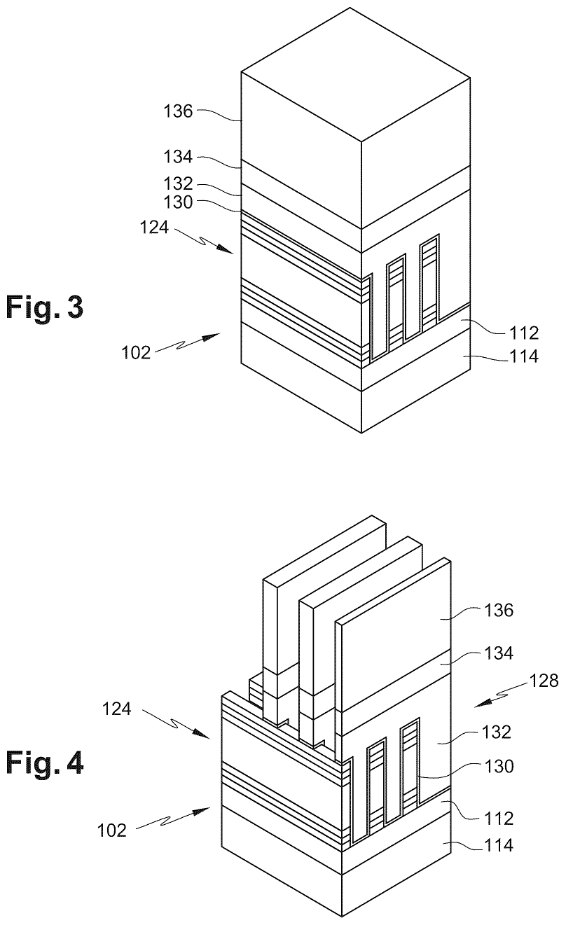

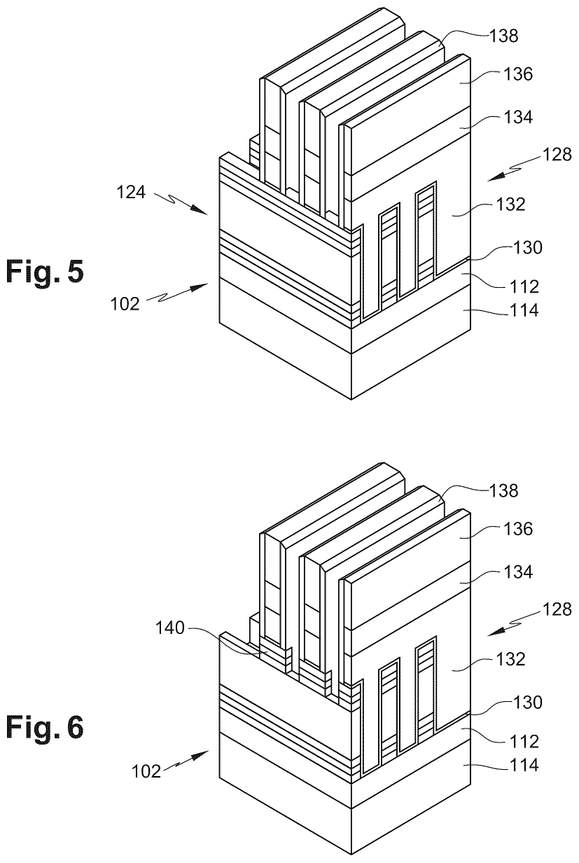

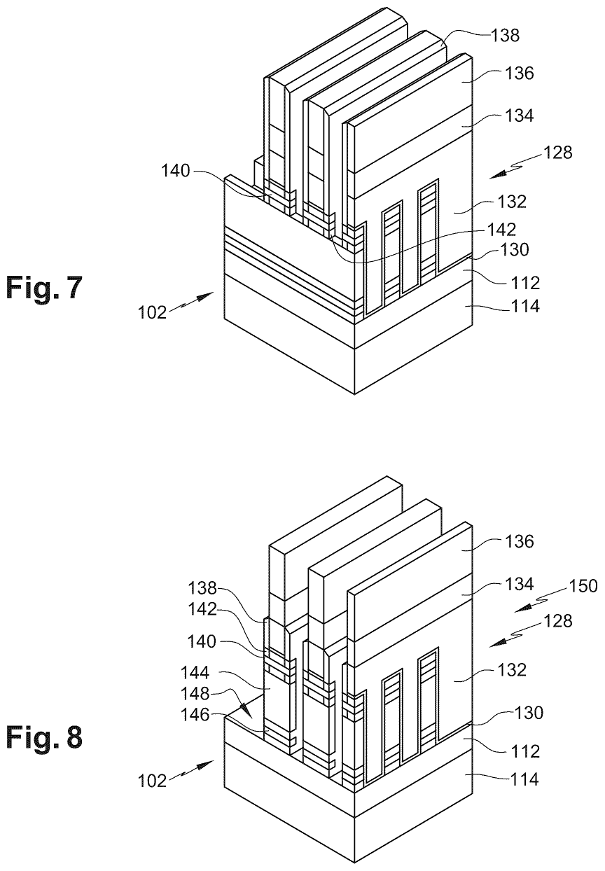

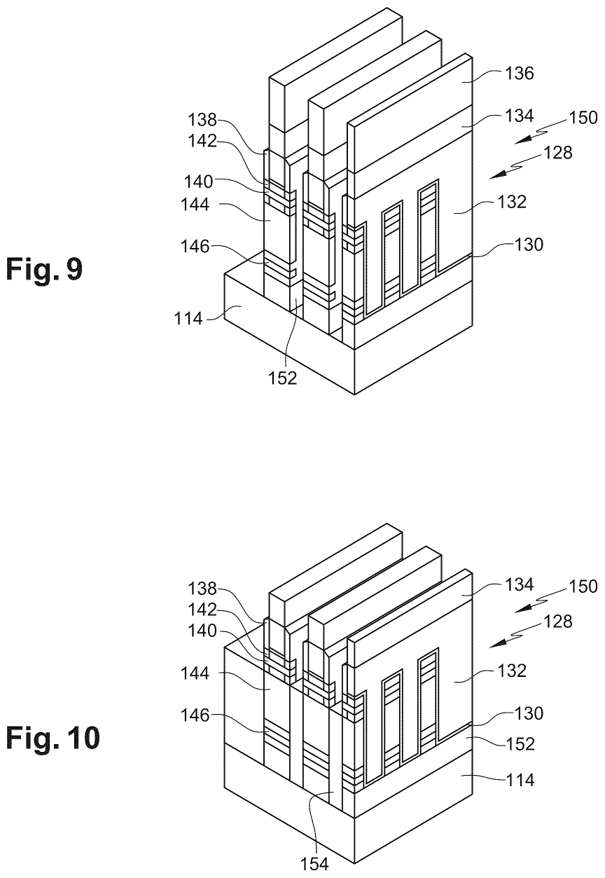

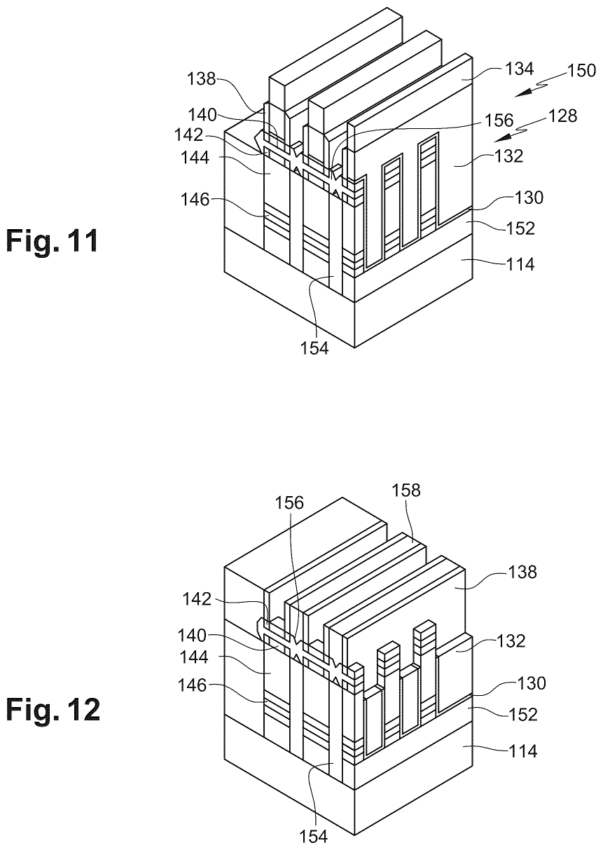

An example of a method of manufacturing a device 100 with CFET transistors is described hereafter in relation with FIGS. 1 to 27.

In the described example of embodiment, the manufacturing of device 100 begins with a substrate 102 on which is formed a stack 104 of first and second semiconductor layers 106, 108 such that the second semiconductor layer 108 is arranged between the first semiconductor layer 106 and substrate 102, stack 104 also comprising a dielectric layer 110 arranged between the first and second semiconductor layers 106, 108.

In the described example of embodiment, substrate 102 is of semiconductor-on-insulator type and comprises a buried dielectric layer 112 arranged between a support layer 114 and a surface semiconductor layer (not shown in the drawings). For example, substrate 102 corresponds to an SOI (“Silicon-On-Insulator”) substrate. The surface semiconductor layer comprises, for example, silicon and has a thickness in the range from approximately 10 nm to 20 nm, and buried dielectric layer 112 comprises, for example, SiO₂ and has a thickness in the range from approximately 15 nm to 145 nm. As a variant, another type of substrate 102 may be used for the manufacturing of device 100.

In the described example of embodiment, starting from substrate 102, an SiGe epitaxial growth is implemented on the surface layer. The germanium concentration used for this epitaxial growth is, for example, in the range from approximately 20% to 40%. This epitaxial growth forms, on the initial surface layer of substrate 102, an SiGe layer having a thickness, for example, in the range from approximately 6 nm to 15 nm. A thermal oxidation (process known as “condensation” or “enrichment”) followed by a removal of the remaining thermal oxide are then implemented, transforming the initial surface layer of substrate 102 into a first sacrificial layer 116 of SiGe directly arranged on buried dielectric layer 112. In the described example, this first sacrificial layer 116 comprises SiGe with a germanium concentration, for example, in the range from approximately 20% to 40% and a thickness in the range from approximately 6 nm to 15 nm.

In the described example of embodiment, starting from the resulting structure, a new step of epitaxial growth of silicon is implemented, forming a silicon layer corresponding to the second semiconductor layer 108, on top of the first sacrificial layer 116. The second semiconductor layer 108 has, for example, a thickness in the range from 6 nm to 15 nm. This epitaxy step is continued by using a germanium concentration, for example, in the range from 20% and 40%, forming a second sacrificial layer 118 of SiGe having a thickness, for example, in the range from 6 nm to 15 nm. A dielectric layer, comprising, for example, SiO₂, SiN, SiCN, SiCO, or a material with a low dielectric permittivity (“low-k”) , is then formed, for example by thermal oxidation of a portion of the second sacrificial layer 118 or by deposition. The thickness of this dielectric layer is, for example, in the range from a few nanometers to 60 nm.

In the described example of embodiment, a second stack of layers (having thicknesses that may be similar to or different from those of the previously-formed layers, but for example within the same ranges as the latter) is also formed. In the described example, this second stack comprises, in this order, a substrate, for example similar to substrate 102 and comprising a support layer and a buried dielectric layer, an SiGe layer called third sacrificial layer 120, a silicon layer corresponding to the first semiconductor layer 106, another SiGe layer called fourth sacrificial layer 122, and a dielectric layer.

In the described example of embodiment, the two stacks of layers formed are then bonded together by their respective upper surfaces, formed by their dielectric layer, the assembly of these dielectric layers forming dielectric layer 110. A removal of the substrate of the second stack, for example by mechanical and/or chemical polishing of the support layer and then of the buried dielectric layer of the substrate of the second stack, is then performed. The resulting stack 104 is shown in FIG. 1.

In this stack 104, the semiconductor materials of the first and second semiconductor layers 106, 108 are selected based on the semiconductors desired to form the channels of the transistors of device 100. In the described example of embodiment, the semiconductor of the first and second semiconductor layers 106, 108 is silicon. As a variant, the first and/or second semiconductor layer 106, 108 may comprise a semiconductor other than silicon, for example Ge, or SiGe, or GeSn, or semiconductor oxides (IGZO, IWO, ITO, etc.) or other III-V materials (InAs, InGaAs, for example).

As a variant, the semiconductors of the first and second semiconductor layers 106, 108 may be different from each other.

In a specific configuration, the crystal orientations of the semiconductors of semiconductor layers 106, 108 may be different from each other. For example, when the semiconductor of one of the first and second semiconductor layers 106, 108 is intended to form the channel of at least one n-type transistor, its crystal orientation may be achieved along the (100) plane and the [110] direction, which enables to promote electron transport in this semiconductor. When the semiconductor of the other of the first and second semiconductor layers 108 is intended to form a p-type transistor (with, for example, a SiGe channel), its crystal orientation may be achieved along the (110) plane and the [110] direction, which enables to promote hole transport in this semiconductor. In the described example, the semiconductors intended to form the channels of transistors of different types preferably have different crystal orientations due to the fact that stack 104 is formed by bonding together two initial stacks formed independently of each other, from different substrates, which has enabled to form the first and second semiconductor layers 106, 108 with different crystal orientations.

In stack 104, the materials of sacrificial layers 116, 118, 120, and 122, between which are located each of the first and second semiconductor layers 106, 108, are selected such that they can be etched selectively over the semiconductors of the first and second semiconductor layers 106, 108. Further, the semiconductors of the first and second semiconductor layers 106, 108 are selected such that they can be etched selectively over the materials of sacrificial layers 116, 118, 120, and 122. In the described example, sacrificial layers 116, 118, 120, and 122 comprise SiGe, which can be etched selectively over the silicon of the first and second semiconductor layers 106, 108.

Stack 104 may comprise a different number of layers than the above-described example. For example, stack 104 may comprise a plurality of first semiconductor layers 106, each arranged between and against two sacrificial layers that can be etched selectively over the first semiconductor layers 106, and/or a plurality of second semiconductor layers 108, each arranged between and against two sacrificial layers that can be etched selectively over the second semiconductor layers 108. The number of first and second semiconductor layers 106, 108 is selected according to the number of stacked semiconductor portions desired to form the channels of the transistors of device 100.

As a variant, stack 104 may comprise layers of additional materials and/or materials different in nature from the previously-described layers.

In the described method example, stack 104 is then etched in such a way that at least a remaining portion of stack 104 forms a fin 124. In the example of FIG. 2, three fins 124 are shown, spaced apart from one another by trenches 126 formed during the etching of stack 104. In this example, fins 124 are formed by lithography and anisotropic etching, with a stop on buried dielectric layer 112. The number of fins 124 formed is selected in particular according to the number of stacks of semiconductor portions desired to form the channels of the transistors of device 100. As a variant, stack 104 could be etched in such a way that the remaining portion(s) of stack 104 each have a shape other than that of a fin. Further, fins 124 may have widths that are similar to or different from one another.

A sacrificial gate 128, or dummy gate, is then formed on top of and around each of fins 124. For this purpose, at least one dummy gate material is deposited on top of and around each of fins 124, and in particular into trenches 126, and then etched according to the pattern desired for dummy gate 128.

In the described example of embodiment, a plurality of steps are carried out sequentially to manufacture dummy gate 128:
conformal deposition of a layer of TEOS (tetraethyl orthosilicate) oxide 130, having a thickness, for example, in the range from approximately 2 nm to 15 nm, covering the bottom walls of trenches 126 and the side and top walls of fins 124;
deposition of a thick layer 132 of amorphous (a-Si) or polycrystalline silicon (poly-Si), for example equal to approximately 380 nm, filling in particular the remaining space in trenches 126 and covering the active area by extending over fins 124 and trenches 126;
chemical-mechanical planarization (CMP) of layer 132 such that a remaining thickness of layer 132 is equal to several tens of nm (approximately 70 nm, for example) above fins 124;
deposition of a first hard mask layer 134 comprising, for example, a nitride such as SiN, and having a thickness for example equal to approximately 30 nm;
deposition of a second hard mask layer 136 comprising, for example, an oxide such as SiO₂, and having a thickness, for example, in the range from a few tens of nanometers to more than 100 nm.

The structure obtained at this stage of the method is shown in FIG. 3.

Dummy gate 128 is then completed by etching the stack of materials previously deposited on top of and around fins 124, according to the pattern desired for dummy gate 128. In the described example of embodiment, a lithography followed by an anisotropic etching of layers 136, 134, and 132, with a stop on layer 130 and on buried dielectric layer 112, are implemented. The portions of layer 130 not covered by the remaining portions of layers 136, 134, and 132 are removed. The structure obtained at this stage of the method is shown in FIG. 4, in which dummy gate 128 is finished.

In the described example, dummy gate 128 comprises a plurality of distinct portions. As a variant, dummy gate 128 may comprise a single portion. Further, the geometry of dummy gate 128 may differ from that described herein. As a variant, steps different from those described hereabove may be implemented to form dummy gate 128. Further, dummy gate 128 may comprise a different number of layers of materials, and/or different materials and/or layer thicknesses than in the previously-described example.

In the described example of embodiment, first gate spacers 138 are formed against side flanks of dummy gate 128. The first gate spacers 138 are, for example, formed by implementing a conformal deposition of at least one dielectric material, for example at least one of the following dielectric materials: SiO₂, SiN, SiCN, SiCO, low-permittivity dielectric material. The thickness of material deposited to form the first gate spacers 138 is, for example, equal to approximately 6 nm. An anisotropic etching with a stop on the third sacrificial layer 120 is then implemented. The structure obtained at this stage of the method is shown in FIG. 5. As a variant, steps different from those described hereabove may be implemented for the forming of the first gate spacers 138. Further, the first gate spacers 138 may comprise a different number of layers of materials, and/or different materials and/or layer thicknesses than in the previously-described example.

In the described example of embodiment, fins 124 are then etched according to the pattern defined by dummy gate 128 and the first gate spacers 138. First, a first anisotropic etching of the first semiconductor layer 106 and of the third and fourth sacrificial layers 120, 122, with a stop on dielectric layer 110, is implemented. The remaining portions of the first semiconductor layer 106 form first semiconductor nanosheets 140 intended to form the first channel of at least a first transistor of device 100. Each of the first semiconductor nanosheets 140 is arranged between remaining portions of the third and fourth sacrificial layers 120, 122. The structure obtained at the end of this etching is shown in FIG. 6.

In the described example of embodiment, first inner spacers 142 are then formed around the lateral ends of the first semiconductor nanosheets 140, and in particular vertically in line with the first gate spacers 138.

For example, the first inner spacers 142 are formed by implementing the following steps:
isotropic and etching of parts of the remaining portions of the third and fourth sacrificial layers 120, 122 selective over the first semiconductor nanosheets 140, this etching defining the locations desired for the first inner spacers 142;
conformal deposition of at least one dielectric material such as SiO₂ or SiN, SiCN, SiCO, or a low-permittivity dielectric material;
anisotropic, then isotropic, etching, or a single isotropic etching, of portions of this dielectric material located outside the desired locations.

The structure obtained at this stage of the method is shown in FIG. 7. As a variant, steps different from those described hereabove may be implemented for the forming of the first inner spacers 142. Further, the first inner spacers 142 may comprise a different number of layers of materials, and/or different materials and/or layer thicknesses than in the previously-described example.

In the described example of embodiment, the etching of fins 128 is continued through dielectric layer 110, the first and second sacrificial layers 116, 118, and the second semiconductor layer 108 by the implementation of an anisotropic etching. The remaining portions of dielectric layer 110 each form a first dielectric portion 144. The remaining portions of the second semiconductor layer 108 form second semiconductor nanosheets 146 intended to form the second channel of at least a second transistor of device 100. Each of the second semiconductor nanosheets 146 is arranged between remaining portions of the first and second sacrificial layers 116, 118. This etching is stopped on a first surface 148 of the substrate 102 formed by buried dielectric layer 112. This etching also removes the portions of the first gate spacers 138 arranged against the side flanks of the first and second hard mask layers 134, 136. The structure obtained at the end of this etching is shown in FIG. 8.

The previously-described steps correspond to an example of forming, on the first surface 148 of substrate 102, of a structure 150 comprising at least:
the first and second semiconductor nanosheets 140, 146 such that the second semiconductor nanosheets 146 are each arranged between one of the first semiconductor nanosheets 140 and substrate 102,
the first dielectric portions 144 arranged between the first and second semiconductor nanosheets 140, 146, and
a dummy gate 128 arranged around a portion of assemblies comprising at least the first and second semiconductor nanosheets 140, 146 and the first dielectric portions 144.

In the described example of embodiment, device 100 comprises a plurality of stacks of one or more second semiconductor nanosheets 146, above each of which is arranged one of the first dielectric portions 144, and a stack of one or more first semiconductor nanosheets 140. In the described example, the stacks of the first and second semiconductor nanosheets 140, 146 are arranged, on the first surface 148 of substrate 102, in rows and columns. According to an example of embodiment, the length of each of the first and second semiconductor nanosheets 140, 146 may be in the range from 5 nm to 50 nm, and the width of each of the first and second semiconductor nanosheets 140, 146 may be in the range from 10 nm to 200 nm.

In the described example of embodiment, an etching, through a first part of the thickness of substrate 102 and from the first surface 148 of substrate 102, of portions of the substrate 102 not covered by structure 150 is then implemented. This etching here corresponds to an anisotropic etching of buried dielectric layer 112, with a stop on support layer 114. Thus, in this example, the first part of the thickness of substrate 102 corresponds to the thickness of buried dielectric layer 112. In FIG. 9, the remaining portions of buried dielectric layer 112 obtained at the end of this etching and which are covered by the remaining portions of fins 128 and by dummy gate 132 are designated by reference 152.

Thus, a single etch mask is used to etch stack 104 across its entire thickness, as well as part of the thickness of substrate 102, which will enable to then form the gates of the CFET transistors in self-aligned manner relative to one another.

In the described example of embodiment, second dielectric portions 154 are then formed in such a way that they cover at least the side flanks of the second semiconductor nanosheets 146 and of the first dielectric portions 144. According to an embodiment, the second dielectric portions 154 comprise at least one low permittivity dielectric material, such as SiOC. Given the steps subsequently implemented, the dielectric material of the second dielectric portions 154 is selected such that it can be etched selectively over the materials of buried dielectric layer 112, spacers 138, 142, and the first hard mask layer 134. Further, in the described example, the second dielectric portions 154 are formed by depositing the dielectric material so as to fill the previously-etched areas, particularly between the remaining portions 152 of buried dielectric layer 112 and the different portions of structure 150, and also covering structure 150. The material deposited and then planarized (by CMP) is subsequently etched for a given period of time in such a way that this dielectric material no longer covers the side flanks of the first semiconductor nanosheets 140. In the described example, the implementation of this etching also removes the second hard mask layer 136, and the second dielectric portions 154 cover the flanks of the remaining portions of the first and second sacrificial layers 116, 118 but do not cover the flanks of inner spacers 142 or the first gate spacers 138. As a variant, the second hard mask layer 136 may be removed during the previous steps, and only the first hard mask layer 134 protects structure 150. The structure obtained at this stage of the method is shown in FIG. 10. Different steps may be implemented to form the second dielectric portions 154.

First source or drain regions 156 are formed from the side flanks of the first semiconductor nanosheets 140. In the described example of embodiment, the first source or drain regions 156 are obtained by implementing an epitaxial growth of a semiconductor, for example n-type doped silicon (for example, by phosphorus doping), the first formed transistor being of type n. The structure obtained at this stage of the method is shown in FIG. 11.

At least a portion of dummy gate 128 is then removed, and at least one electrically-conductive portion of the first gate is formed. In the described embodiment, dummy gate 128 is partially removed by carrying out the following steps:
deposition and then CMP of a first sacrificial material 158, corresponding for example to silicon oxide having a thickness for example in the range from approximately 50 nm to 400 nm, covering in particular the first source or drain regions 156;
etching of the first hard mask layer 134 and then of a portion of the layers 130, 132 of dummy gate 128, this etching being time-controlled so as to preserve portions of the dummy gate 128 arranged at least against the second semiconductor nanosheets 146 and the remaining portions of the first and second sacrificial layers 116, 118. In the described example, the remaining portions of dummy gate 128 also cover a portion of the flanks of the first dielectric portions 144. The structure obtained at this stage of the method is shown in FIG. 12.

The remaining portions of the third and fourth sacrificial layers 120, 122, between which are located the first semiconductor nanosheets 140, are then removed by the implementation of an etching of these portions selective over the first semiconductor nanosheets 140, so as to disengage the first semiconductor nanosheets 140 intended to form the first channel of the first transistor of device 100. The first semiconductor nanosheets 140 here form suspended semiconductor portions around which the first gate is intended to be formed. The structure obtained at this stage of the method is shown in FIG. 13.

A first gate dielectric 160 and one or more electrically-conductive portions 162 of the first gate are then formed around the first semiconductor nanosheets 140. In the described example, around each first semiconductor nanosheet 140, a stack of the first gate dielectric 160 comprising, for example, a high-permittivity, or high-k, dielectric material, for example HfO₂, is formed and a first metal layer of the electrically-conductive portions 162, for example TiN, is conformally deposited around the first semiconductor nanosheets 140, and more generally against the walls of the spaces formed by the partial removal of dummy gate 128. As an example, the thickness of the first gate dielectric 160 is equal to approximately 2 nm, and that of the first metal layer of the electrically-conductive portions 162 is equal to approximately 3 nm. The remaining space formed by the partial removal of dummy gate 128 is filled by a second metal layer of electrically-conductive portions 162, comprising, for example, tungsten. This second metal layer is then planarized by CMP, with a stop on the first sacrificial material 158. The first gate, designated with reference 164, thus formed has a structure similar to that of an all-around gate of a GAA-type transistor.

The structure obtained at this stage of the method is shown in FIG. 14. As a variant, steps different from those described hereabove may be implemented for the forming of the first gate 164. Further, the first gate 164 may comprise a different number of layers of materials, and/or different materials and/or layer thicknesses than those of the previously-described example.

In the described example of embodiment, the second metal layer of electrically-conductive portions 162 is then partially etched, after which the spaces formed by this etching are filled with portions of dielectric material 166, for example silicon nitride, deposited and planarized by CMP. The first sacrificial material 158 is then etched selectively over the materials exposed to this etching, that is, over the first gate spacers 138, the first source or drain regions 156, and the portions of dielectric material 166 in the described example. First metal contacts 168 of the first source or drain regions 156 are then formed in the spaces formed by the etching of the first sacrificial material 158. For example, these first metal contacts 168 may be formed by successively depositing a titanium layer having a thickness equal to approximately 2 nm, a TiN layer having a thickness equal to approximately 3 nm, and filling the remaining space with tungsten. A CMP planarization with a stop on portions of dielectric material 166 is then implemented.

The structure obtained at this stage of the method is shown in FIG. 15. As a variant, steps different from those described hereabove may be implemented for the forming of portions of dielectric material 166 and of the first metal contacts 168. Further, the portions of dielectric material 166 and/or the first metal contacts 168 may comprise a different number of layers of materials, and/or different materials and/or layer thicknesses than in the previously-described example.

At this stage of the method, the first source or drain regions 156 and the first gate 164 of the first transistor are connected to metal contacts, which may then be connected to the various metal lines of device 100 formed during the so-called “back-end” steps.

The resulting assembly is turned over, after which an etching of a second part of the thickness of substrate 102 from a second surface 170 of substrate 102, opposite to first surface 148, is implemented in such a way that at least a remaining portion of substrate 102 is arranged against structure 150. In the described example of embodiment, this is achieved by first bonding a support substrate, or carrier, to the front surface of the formed stack, that is, the side where dielectric portions 166 and the first metal contacts 168 have been formed. This carrier substrate is not shown in the drawings. Support layer 114 is then removed, for example by mechanical and/or chemical polishing, with a stop on the remaining portions 152 of buried dielectric layer 112 and on the second dielectric portions 154. The structure obtained at this stage of the method is shown in FIG. 16.

In the described example of embodiment, the second dielectric portions 154 are then etched selectively over the remaining portions 152 of buried dielectric layer 112 for a period of time such that the flanks of the second semiconductor nanosheets 146 and of the remaining portions of the first and second sacrificial layers 116, 118 are no longer covered by the second dielectric portions 154. The structure obtained at this stage of the method is shown in FIG. 17.

In the described example of embodiment, second inner spacers 172 are then formed around the lateral ends of the second semiconductor nanosheets 146. In the described example of embodiment, the steps implemented for the forming of the second inner spacers 172 are, for example, similar to those implemented to form the first inner spacers 142. The structure obtained at this stage of the method is shown in FIG. 18.

Second source or drain regions 174 are then formed from the side flanks of the second semiconductor nanosheets 146. In the described embodiment, these second source or drain regions 174 are obtained by implementing an epitaxial growth of a semiconductor, for example, silicon doped with a type opposite to that of the first source or drain regions 156 (p-type doped, with boron, in this example), the second transistor formed being of type p. The structure obtained at this stage of the method is shown in FIG. 19. In this structure, the second source or drain regions 174 are arranged vertically in line with the first source or drain regions 156, given the same etch mask previously used to etch stack 104 across its entire thickness as well as part of the thickness of substrate 102.

A deposition and then a CMP of a second sacrificial material 176 covering the second source or drain regions 174 are then implemented. The second sacrificial material 176 is selected such that it can be etched selectively over a gate spacer of the second transistor as well as a material for protecting the gate of the second transistor, which will be formed later on. Further, the second sacrificial material 176 is here selected such that the materials of the remaining portions 152 of buried dielectric layer 112, of dummy gate 128, Of the first dielectric portions 144, and of the electrically-conductive portions of the gate of the second transistor (formed later on) can be etched selectively over this second sacrificial material 176. As an example, by forming the gate spacers and the gate protection materials with SiN or a SiN-derived material, and the first dielectric portions 144 with a low-permittivity dielectric such as SiOC, the second sacrificial material 176 may correspond to aluminum oxide AlOₓ. The structure obtained at this stage of the method is shown in FIG. 20.

The remaining portions 152 of the buried dielectric layer 112 are then etched selectively over the second sacrificial material 176, thereby defining the location of the future gate of the second transistor, which will then be self-aligned with the first gate of the first transistor due to the fact that a single photolithography mask was used to define the gate locations of both transistors. The structure obtained at this stage of the method is shown in FIG. 21.

In the described example of embodiment, second gate spacers 178 are then formed in the spaces formed by the previous etching of the remaining portions 156 of buried dielectric layer 112, against the side flanks of the portions of the second sacrificial material 176. As with the forming of the first gate spacers 138, the second gate spacers 178 are, for example, formed by implementing a conformal deposition of at least one dielectric material, for example SiO₂, SiN, SiCN, SiCO, or any low-permittivity dielectric material. The thickness of the material deposited to form the second gate spacers 178 is, for example, equal to approximately 6 nm. An anisotropic etching with a stop on the second sacrificial material 176 can then be implemented to remove the portions of this material deposited on the second sacrificial material 176. The structure obtained at this stage of the method is shown in FIG. 22. As a variant, steps different from those described hereabove may be implemented to form the second gate spacers 178. Further, the second gate spacers 178 may comprise a different number of layers of materials, and/or different materials and/or layer thicknesses than in the previously described example.

In the described example of embodiment, the remaining portions of dummy gate 128 are then removed by etching, with a stop on the first gate dielectric 160. The structure obtained at this stage of the method is shown in FIG. 23.

In the described example of embodiment, an insulator, for example a low-permittivity dielectric material such as SiOC, is then deposited, planarized, and then etched so as to leave a layer of this insulator 180 between the first dielectric portions 144, on the portions of the first gate dielectric 160 and the walls formed by the first gate spacer 138 exposed by the removal of the remaining portions of dummy gate 128. This insulator here enables to electrically insulate the transistor gates from each other. The structure obtained at this stage of the method is shown in FIG. 24.

The remaining portions of the first and second sacrificial layers 116, 118, between which are located the second semiconductor nanosheets 146, are then removed by the implementation of an etching of these portions selective over the second semiconductor nanosheets 146, so as to expose the second semiconductor nanosheets 146 intended to form the second channel of the second transistor of device 100. The second semiconductor nanosheets 146 here form suspended semiconductor portions around which the second gate is intended to be formed. The structure obtained at this stage of the method is shown in FIG. 25.

As with the forming of the first gate, steps are then implemented to form the second gate of the second transistor. Thus, a second gate dielectric 182 and one or more electrically-conductive portions 184 of the second gate are then formed around the second semiconductor nanosheets 146. In the described example, around each second semiconductor nanosheet 146, a stack of the second gate dielectric 182, comprising, for example, a high-permittivity dielectric material such as HfO₂, and a first metal layer of electrically-conductive portions 184, for example TiN, is deposited conformally around the second semiconductor nanosheets 146 and against the walls formed by the second gate spacers 178. As an example, the thickness of the second gate dielectric 182 is equal to approximately 2 nm, and that of the first metal layer of the electrically-conductive portions 184 is equal to approximately 3 nm. The remaining space is filled with a second metal layer of electrically-conductive portions 184, comprising, for example, tungsten. This second metal layer is then planarized by CMP, with a stop on the second sacrificial material 176. The second gate, designated by reference 186, thus formed has a structure similar to that of an all-around gate of a GAA-type transistor. In the resulting structure, the first and second gates 164, 186 are electrically insulated from each other by insulating layer 180. For example, the first gate dielectric 160 may comprise one or more materials different from that or those of the second gate dielectric 182, and/or the first gate 164 may comprise one or more metals having a work function different from that or those of the second gate 186, and thus allow independent adjustment of the threshold voltages of the different types of transistors of device 100.

The resulting structure is shown in FIG. 26. As a variant, steps different from those described hereabove may be implemented for the forming of the second gate 186. Further, the second gate 186 may comprise a different number of layers of materials, and/or materials and/or layer thicknesses different from those of the previously-described example.

In the described embodiment, the second metal layer of electrically-conductive portions 184 is then partially etched, and the spaces formed by this etching are filled with portions of dielectric material 188, for example silicon nitride, deposited and planarized by CMP. The second sacrificial material 176 is then etched selectively over the materials exposed to this etching, that is, over the second gate spacers 178, the second source or drain regions 174, and the portions of dielectric material 188 in the described example. Second metal contacts 190 of the second source or drain regions 174 are then formed in the spaces formed by the etching of the second sacrificial material 176. For example, these second metal contacts 190 may be formed by successively depositing a titanium layer having a thickness approximately equal to 2 nm, a TiN layer having a thickness approximately equal to 3 nm, and by filling the remaining space with tungsten. A CMP planarization with a stop on the portions of dielectric material 188 is then implemented.

The resulting device 100, in which the forming of the first transistor 192 and of the second transistor 194 is complete, is shown in FIG. 27. Other steps, such as the BEOL (“Back End Of Line”) process, are implemented and not described herein.

A variant of the previously-described method is described hereafter.

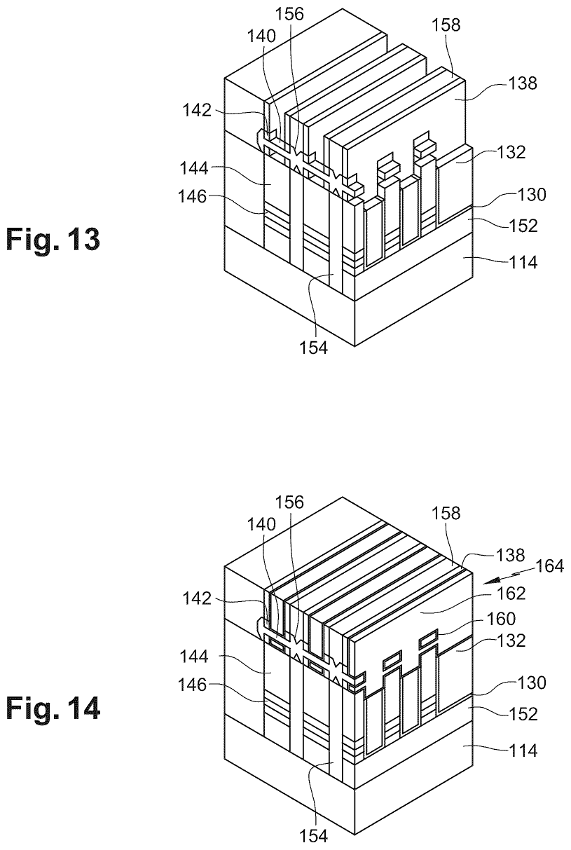

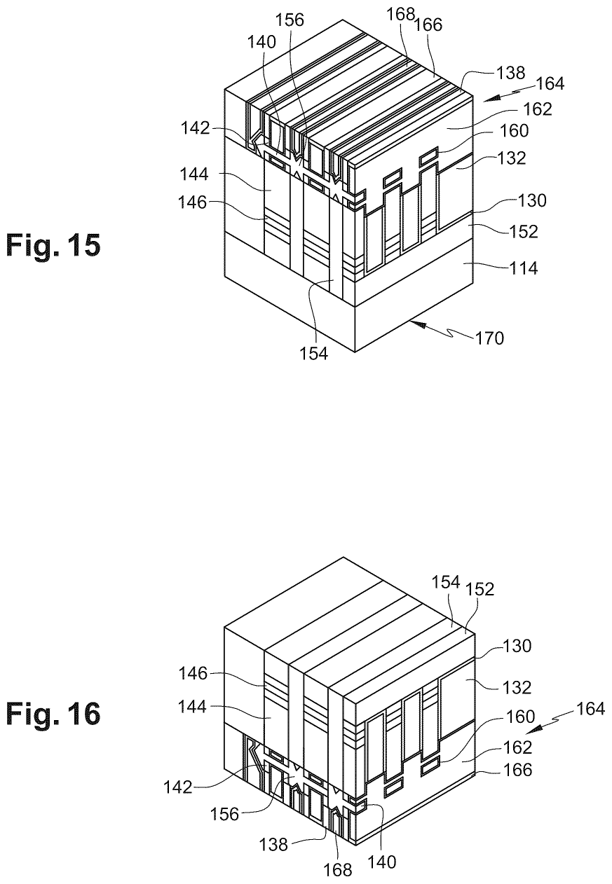

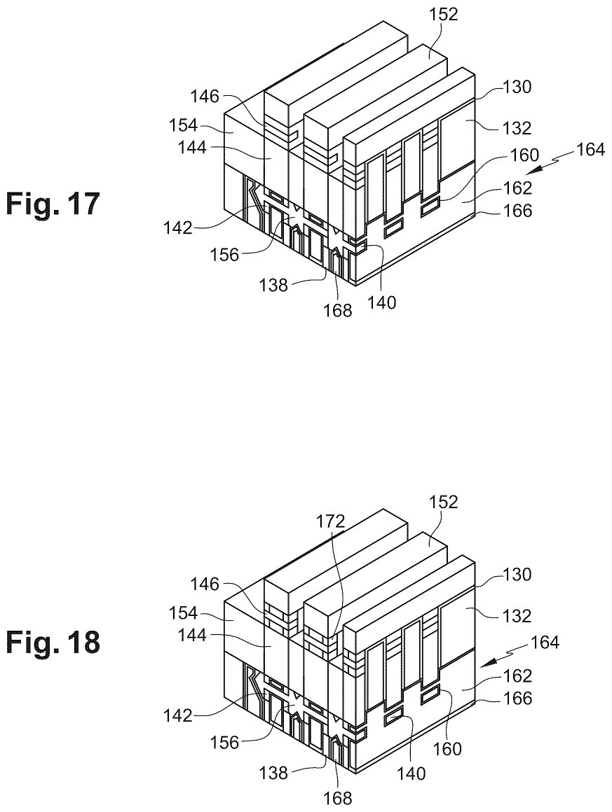

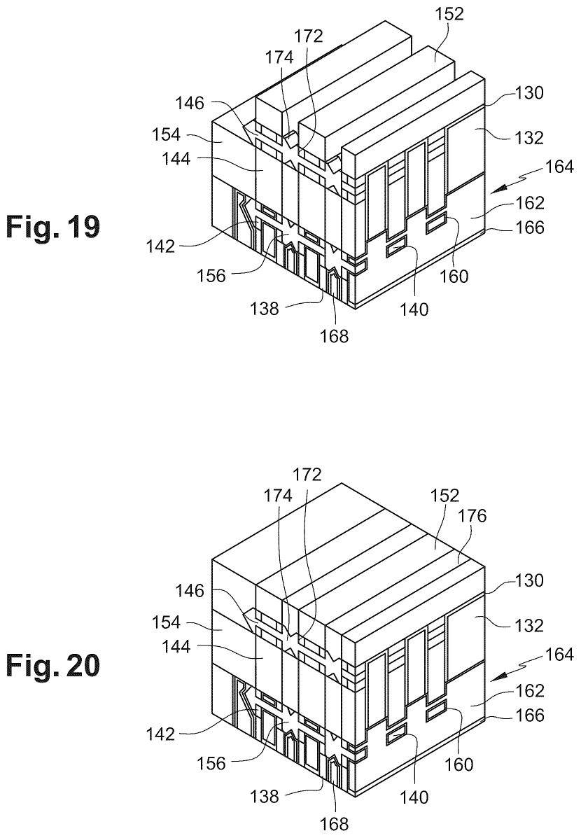

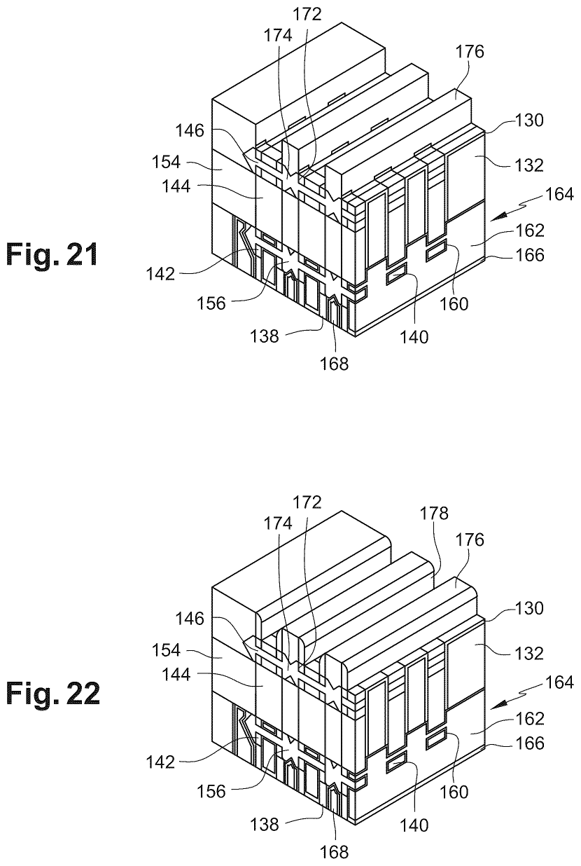

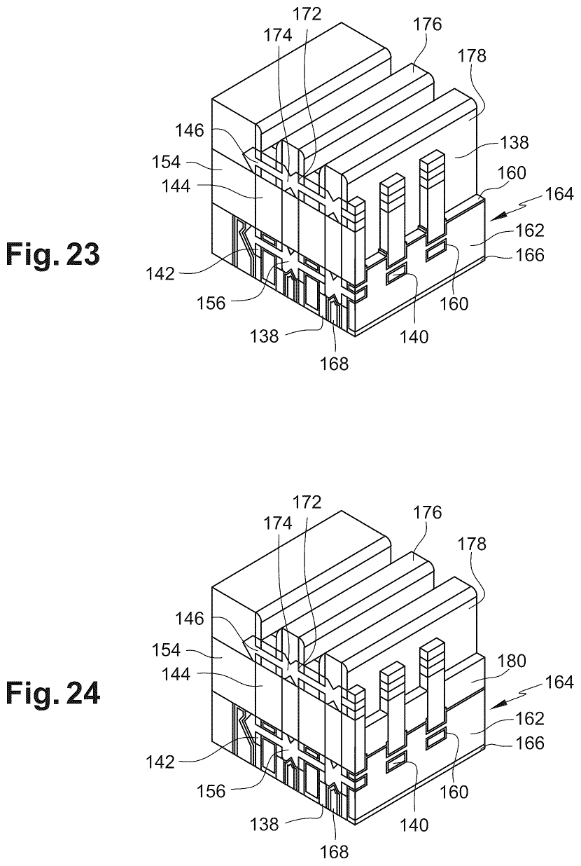

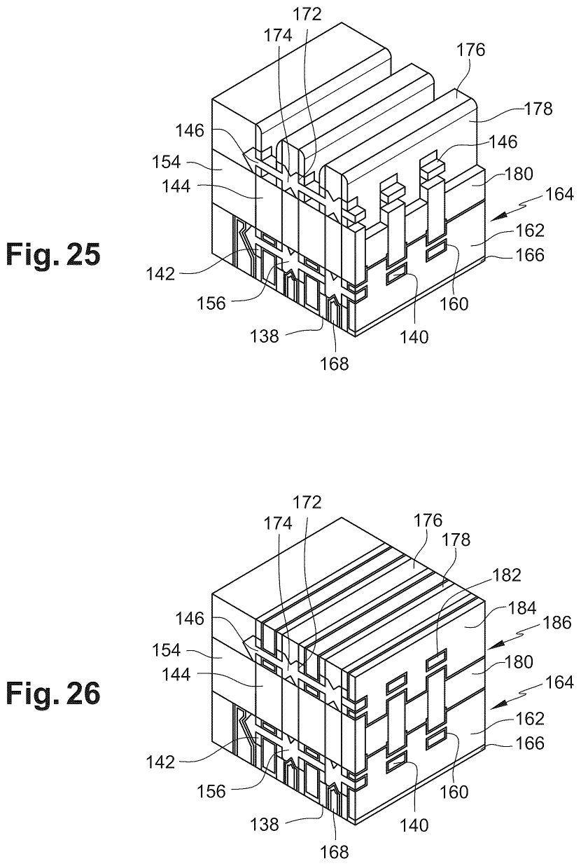

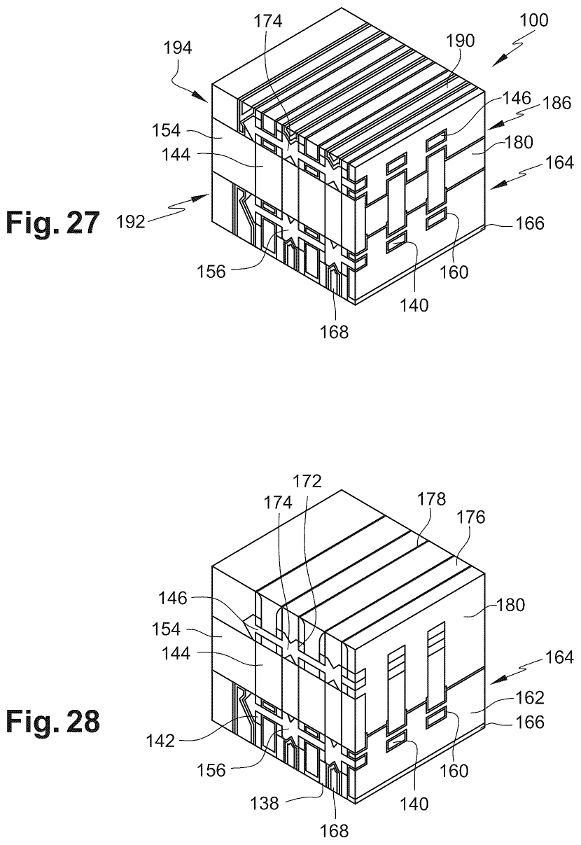

The steps previously-described in relation with FIGS. 1 to 23 are first carried out. However, in this embodiment, the second sacrificial material 176 is an amorphous semiconductor material of a different nature than that of the second semiconductor nanosheets 146. For example, if the second semiconductor nanosheets 146 and the second source or drain regions 174 contain silicon, the second sacrificial material 176 may be, for example, amorphous SiGe. Insulating layer 180 is then deposited and planarized with a stop on the second sacrificial material 176. The structure obtained at this stage of the method is shown in FIG. 28.

A partial etching of the second sacrificial material 176 is then performed, as shown, for example, in FIG. 29. Dielectric portions 196, comprising, for example, oxide, are then deposited in the spaces formed by the previous etching, on the remaining sacrificial material 178. This combination amorphous semiconductor for the second sacrificial material 176 and of oxide for dielectric portions 196 enables to respect the required etching selectivities, in particular:
the oxide of buried dielectric layer 112 can be etched selectively over the second sacrificial material 176;

the second sacrificial material 176 can be etched selectively over dielectric portions 196.

The previously-described method forms device 100, which comprises at least:
a first field-effect transistor 192 of a first conductivity type comprising a first channel formed, in this example, by at least a first semiconductor nanosheet 140, first source or drain regions 156, and a first gate 164 arranged around the first channel;
a second field-effect transistor 194 of a second conductivity type, opposite to the first conductivity type, comprising a second channel formed, in this example, by at least one second semiconductor nanosheet 146, second source or drain regions 174, and one second gate 186 arranged around the second channel;
a first dielectric portion 144 arranged between the first and second gates 164, 186 and configured to electrically insulate the first and second gates from each other;
second dielectric portions 154, distinct from the first dielectric portion 144, each arranged between one of the first source or drain regions 156 and one of the second source or drain regions 174 and configured to electrically insulate these first and second source or drain regions 156, 174 from each other;
and wherein side flanks of the first gate 164 are aligned with, or arranged vertically in line with, side flanks of the second gate 186.

In the above-described embodiments, the first and second transistors 192, 194 both comprise channels formed by first and second silicon semiconductor nanosheets 140, 146. In a variant, the channel of the p-type transistor may be made of SiGe, in which case the sacrificial layers between which the SiGe layer is initially arranged may comprise silicon. The etching of the sacrificial layers being implemented during two different steps of the method of manufacturing device 100, the use of different semiconductors to form the channels of the first and second transistors does not require the addition of a step, but simply an adaptation of some of them, in particular the chemistries of the selective etching of Si and SiGe.

Thus, when the first semiconductor layer 106 comprises silicon, the third and fourth sacrificial layers 120, 122 may comprise SiGe, and when the first semiconductor layer 106 comprises SiGe, the third and fourth sacrificial layers 120, 122 may comprise silicon. In both of these configurations, when the second semiconductor layer 108 comprises silicon, the first and second sacrificial layers 116, 118 may comprise SiGe, and when the second semiconductor layer 108 comprises SiGe, the first and second sacrificial layers 116, 118 may comprise silicon.

The first transistor may be of type n and the second transistor may be of type p, or the first transistor may be of type p and the second transistor may be of type n.

In the various examples of embodiment, the first dielectric portion 144 may comprise at least one material having a chemical composition different from that of at least one material of each of the second dielectric portions 154, the materials of these dielectric portions 144, 154 preferably being low-permittivity dielectric materials. Thus, it is possible to significantly decrease the parasitic electrical capacitances between the elements of the first transistor 192 and those of the second transistor 194.

In the various examples of embodiments, the electrically-conductive portion 162 of the first gate 164 may comprise at least one metal having a work function value different from that of at least one metal of the electrically-conductive portion 184 of the second gate 186. The selection of metals having different work functions for the electrically-conductive portions 162, 84 of the first and second gates 164, 186 enables to perform an adjustment of the threshold voltage independently for each of transistors 192, 194. For example, the electrically-conductive portions 162, 184 may respectively comprise TiN and W, or any other suitable metallic material such as at least one of the following materials: Al, Ni, Ti, TaN, TiC, TaC, etc.

In the various examples of embodiments, the gate dielectrics 160, 182 may comprise at least one of the following materials: HfO₂, HfSiO₄, HfO₂, La₂O₃, LaAlO₃, ZrO₂, ZrSiO₄, Ta₂O₅, TiO₂, SrTiO₃, Al₂O₃. A high-permittivity (“high-k”) dielectric material may correspond to a dielectric material having a dielectric permittivity greater than that of SiO₂, for example greater than 3.9.

The sequence of the various steps of the manufacturing method may be different from the previously-described example, in such a way as to optimize one or more parameters of device 100, such as performance or reliability.

Thus, in the previously-described example of embodiment, the first source or drain regions 156 of the first transistor 192 are formed, after which the first gate 164 of the first transistor 192 is formed, after which the second source or drain regions 174 of the second transistor 194 is formed, and then the second gate 186 of the second transistor 194 is formed.

According to a first variant, it is possible for the second gate 186 of the second transistor to be formed after the first gate 164 of the first transistor 192 and before the second source or drain regions 174 of the second transistor 194.

According to a second variant, it is possible for the first gate 164 of the first transistor 192 to be formed, then for the first source or drain regions 156 of the first transistor 192 to be formed, then for the second source or drain regions 174 of the second transistor 194 to be formed, and then for the second gate 186 of the second transistor 194 to be formed.

According to a third embodiment, it is possible for the first gate 164 of the first transistor 192 to be formed, then for the first source or drain regions 156 of the first transistor 192 to be formed, then for the second gate 186 of the second transistor 194 to be formed, and then for the second source or drain regions 174 of the second transistor 194 to be formed.

In the previously-described embodiment, as well as in the above-discussed first, second, and third variants, the second gate 186 of the second transistor 194 and the second source or drain regions 174 of the second transistor 194 are formed from the back side of the initially formed-assembly, that is, on the side of the surface initially occupied by substrate 102, and the first gate 164 of the first transistor 192 and the first source or drain regions 156 of the first transistor 192 are formed from the front side of the initially-formed assembly.

According to other variants, it is possible for the second gate 186 of the second transistor 194 to be formed from the back side of the initially-formed assembly, that is, on the side of the surface initially occupied by substrate 102, and for the first gate 164 of the first transistor 192 and the first and second source or drain regions 156, 174 of the first and second transistors 192, 194 to be formed from the front side of the initially-formed assembly.

An example of a fourth variant of the manufacturing method, in which the second gate 186 of the second transistor 194 is formed from the back side of the initially-formed assembly, and the first gate 164 of the first transistor 192 and the first and second source or drain regions 156, 174 of the first and second transistors 192, 194 are formed from the front side of the initially-formed assembly, is described hereafter.

The steps previously described in relation with FIGS. 1 to 5 are first carried out.

Fins 124 are then etched in accordance with the pattern defined by dummy gate 128 and the first gate spacers 138, with a stop on buried dielectric layer 112. This etching forms structure 150 comprising, in particular, the first semiconductor nanosheets 140, the first dielectric portions 144, and the second semiconductor nanosheets 146.

The first and second inner spacers 142, 172 are then formed. When the materials of the channels of the first and second transistors 192, 194 are different, the forming of the inner spacers 172 of the second transistor 194 involves a partial etching of inner spacers 142 so as not to expose the channel to the implemented selective etching. If the materials of the channels of the first and second transistors 192, 194 are similar, for example made of silicon, the first and second inner spacers 142, 172 are formed, for example, in a manner similar to that previously described in relation with FIGS. 7 and 18.

The etching previously described in relation with FIG. 9, forming in this example the remaining portions 152 of buried dielectric layer 112, is then implemented.

Dielectric portions similar to the second dielectric portions 154 are then formed such that they cover at least the side flanks of the second semiconductor nanosheets 146, the second inner spacers 172, and optionally at least a first portion of the side flanks of the first dielectric portions 144, but do not cover the side flanks of the first semiconductor nanosheets 140 or those of the first inner spacers 142. The steps implemented for the forming of these dielectric portions and the material(s) used are, for example, of same nature as those previously described in relation with FIG. 10.

A protective dielectric layer is then formed, for example in the form of a “liner”, that is, in the form of a conformal deposit, along the side flanks of the elements not covered by the dielectric portions, that is, by covering the side flanks of the first semiconductor nanosheets 140, of the first inner spacers 142, and optionally at least a second portion of the side flanks of the first dielectric portions 144 not covered by the dielectric portions.

The dielectric portions are then etched selectively over the protective dielectric layer for a period of time such that the side flanks of the second semiconductor nanosheets 146 and of the second inner spacers 172 are no longer covered by the dielectric portions.

The second source or drain regions 174 are then formed from the side flanks of the second semiconductor nanosheets 146. The step(s) implemented for the forming of the second source or drain regions 174 are, for example, similar to those previously described in relation with FIG. 19.

The protective dielectric layer is then removed, for example by etching.

The second dielectric portions 154 are then formed so as to cover the second source or drain regions 174 while not covering the side flanks of the first semiconductor nanosheets 140 and of the first inner spacers 142. The steps implemented for the forming of the second dielectric portions 154 are, for example, similar to those previously implemented to form the previous dielectric portions.

The first source or drain regions 156 are then formed from the side flanks of the first semiconductor nanosheets 140. The step(s) implemented for the forming of the first source or drain regions 156 are, for example, similar to those previously described in relation with FIG. 11.

A deposition and then a CMP of the first sacrificial material 158, covering in particular the first source or drain regions 156, is then performed, as previously described in relation with FIG. 12.

The steps of etching of the first hard mask layer 134 and of a portion of dummy gate 128, of etching of the third and fourth sacrificial layers 120, 122 enabling to disengage the first semiconductor nanosheets 140, and of forming of the first gate 164, previously described in relation with FIGS. 12 to 14, are implemented.

The steps previously described in relation with FIG. 15, forming the portions of dielectric material 166 and the first metal contacts 168, are then carried out.

Finally, the steps previously described in relation with FIGS. 21 to 27 are carried out, completing the manufacturing of device 100.

Thus, in the above-described fourth variant, the first and second source or drain regions 156, 174 are formed, after which the first gate 164 of the first transistor 192 is formed, after which the second gate 186 of the second transistor 194 is formed.

In an example of a fifth variant of the manufacturing method, in which, as in the previously-described fourth variant, the second gate 186 of the second transistor 194 is formed from the back side of the initially-formed assembly, and the first gate 164 of the first transistor 192 and the first and second source or drain regions 156, 174 of the first and second transistors 192, 194 are formed from the front side of the initially-formed assembly, the first gate 164 of the first transistor 192 is formed, after which the first and second source or drain regions 156, 174 are formed, after which the second gate 186 of the second transistor 194 is formed.

In these different variants, when the source or drain regions of one or the other of the transistors are formed after the gate of this transistor, these source or drain regions may be formed by implementing a low-temperature epitaxy, for example between approximately 350 °C and 500 °C.

In the different previously-described variants, when the first and second source or drain regions 156, 174 and the electrically-conductive portions 162 of the first gate 164 are formed before the etching of the second part of the thickness of substrate 102, the second source or drain regions 174 may be formed before the first source or drain regions 156, which are in this case protected by a sacrificial material (corresponding to the protective dielectric layer in the above description of the fourth variant) deposited prior to the forming of the second source or drain regions 174.

Other alternative embodiments of device 100 can be envisaged.

As a variant, the channels and the source or drain regions of the first and second transistors 192, 194 may comprise a so-called “2D” or two-dimensional material and/or a semiconductor oxide. Such a 2D material is, for example, selected from among transition metal dichalcogenides, having MX₂ as a composition, with M selected from among molybdenum or tungsten, and X selected from among sulfur, selenium, or tellurium. A semiconductor oxide comprises, for example, IGZO (indium-gallium-zinc oxide), In₂O₃, IWO (indium-doped tungsten oxide), ITO (indium-tin oxide), IAZO (indium-aluminum-zinc oxide), InGaZnO, InGaO, InZnO, or an amorphous semiconductor oxide.

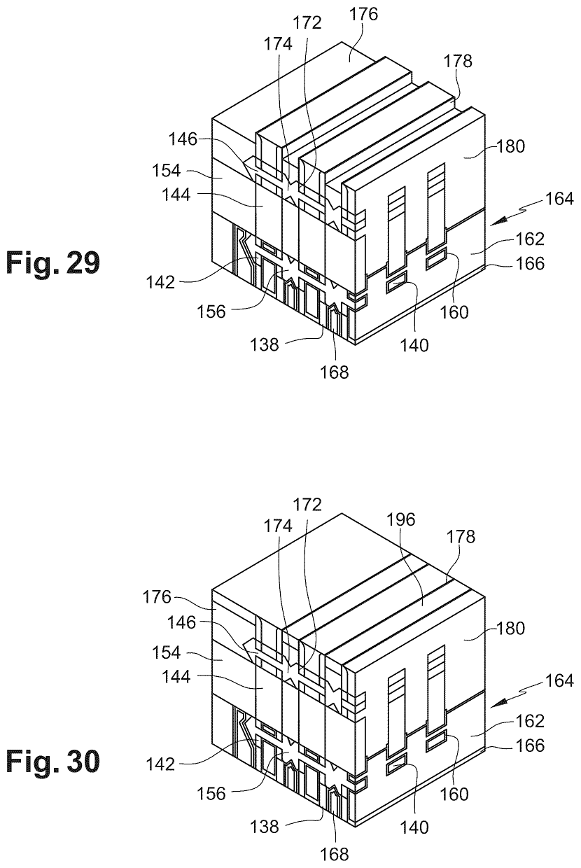

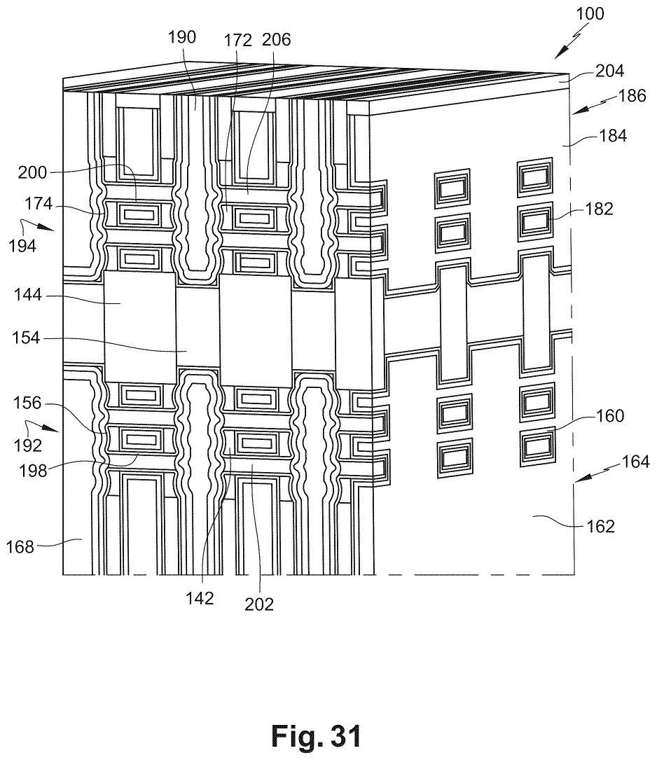

An example of a device 100 according to such a variant is shown in FIG. 31.

In this example, the first channel and the first source or drain regions 156 comprise at least one first layer of 2D material and/or semiconductor oxide designated by reference 198, and the second channel and the second source or drain regions 174 comprise at least one second layer of semiconductor oxide and/or material designated by reference 200. Other elements of the device 100 according to this example are described in the following manufacturing method.

A first example of a method of manufacturing such a device 100 is described hereafter.

First and second stacks of layers are initially formed and bonded to each other by the dielectric layer 110 intended to form, after etching, the first dielectric portions 144, and each comprise an alternation of first and second layers that may be of different nature, for example dielectric (oxide, nitride), semiconductor, or metallic, but which are such that they can be etched selectively over one another. As an example, the first and second layers of each of the first and second stacks of layers may correspond to an alternating stack of Si/SiGe layers. Other materials are possible.

Fins 124 are formed and then etched as in the previous examples, so as to obtain stacks of nanosheets formed by the remaining portions of the layers in the stacks and of dielectric layer 110, and dummy gate 128. Substrate 102 is also etched in such a way as to obtain the remaining portions 152 arranged under the stacks of nanosheets. As in the previous examples, the use of a same mask to etch the entire thickness of the stack and at least part of the thickness of the substrate will allow for the self-alignment of the first and second gate, which will be manufactured afterwards.

The first and second inner spacers 142, 172 are then formed.

The second dielectric portions 154 are then formed over the entire height of the resulting structure, after which dummy gate 128 is etched. The nanosheets from the first or second layers of the first stack are then etched so that the first gate 164 is subsequently formed around the remaining nanosheets of the first stack. The portions of dielectric material 166 are then formed.

The second dielectric portions 154 are then etched across part of their thickness to allow access to and an etching of the remaining nanosheets of the first stack. A first layer 198 of 2D material and/or semiconductor oxide is then conformally deposited in the locations formed by the etching of the remaining nanosheets of the first stack, forming the channel of the first transistor 192, as well as against the sidewalls formed by gate spacers 138 and on the remaining portions of the second dielectric portions 154, forming the first source or drain regions 156 of the first transistor 192. When voids are still present, after this deposition, in the locations formed by the etching of the remaining nanosheets of the first stack, a dielectric material 202 is deposited in order to fill these voids.

One or more metallic materials are then deposited in the remaining spaces, against the portions of the first layer of 2D material and/or semiconductor oxide 198 forming the first source or drain regions 156, to form the first source or drain contacts 168 of the first transistor 192. This or these metallic materials are, for example, based on Ti, TiN, W, or other metals enabling to ensure a low contact resistance, such as Bi, Ni, Au, Sb, etc.

The assembly is then turned over to form the second transistor 194.

The remaining portions of substrate 102 are etched, after which the portions of material present, occupying the space intended for the forming of the second gate 186, are etched. The nanosheets originating from the first or second layers of the second stack are then etched so that the second gate 186 is formed around the remaining nanosheets of the second stack. Portions of dielectric material 204 similar to portions 166 are then formed on the second gate 186.

The second dielectric portions 154 are then etched across part of their thickness to allow access to and etching of the remaining nanosheets of the second stack. The second layer 200 of 2D material and/or semiconductor oxide is then conformally deposited in the locations formed by the etching of the remaining nanosheets of the second stack, forming the channel regions of the second transistor 194, as well as against the sidewalls formed by the gate spacers and on the remaining portions of the second dielectric portions 154, forming the second source or drain regions 174 of the second transistor 194. If voids are still present, after this deposition, in the locations formed by the etching of the remaining nanosheets of the second stack, a dielectric material 206 is deposited in order to fill these voids.

One or more metallic materials are then deposited in the remaining spaces, against the portions of the second layer 200 of 2D material and/or semiconductor oxide forming the second source or drain regions 174, to form the second source or drain contacts 190 of the second transistor 194.

In the above-described first method example, in which device 100 comprises the layers of 2D material and/or semiconductor oxide 198, 200, the first gate 164 of the first transistor 192 is formed, after which the first channel and the first source or drain regions 156 based on 2D material and/or semiconductor oxide of the first transistor 192 are formed, after which the second gate 186 of the second transistor 194 is formed, after which the second channel and the second source or drain regions 174 based on 2D material and/or semiconductor oxide of the second transistor 194 are formed.

According to a second example of a method of manufacturing this device 100, the first gate 164 of the first transistor 192 is formed, after which the first channel and the first source or drain regions 156 made of 2D material and/or of semiconductor oxide of the first transistor 192 are formed, after which the second channel and the second source or drain regions 174 based on 2D material and/or on semiconductor oxide of the second transistor 194 are formed, after which the second gate 186 of the second transistor 194 is formed.

According to a third example of such a method of manufacturing this device 100, the first channel and the first source or drain regions 156 based on 2D material and/or on semiconductor oxide of the first transistor 192 are formed, after which the first gate 164 of the first transistor 192 is formed, after which the second channel and the second source or drain regions 174 based on 2D material and/or semiconductor oxide of the second transistor 194 are formed, after which the second gate 186 of the second transistor 194 is formed.

According to a fourth example of such a method of manufacturing this device 100, the first channel and the first source or drain regions 156 based on 2D material and/or semiconductor oxide of the first transistor 192 are formed, after which the first gate 164 of the first transistor 192 is formed, after which the second gate 186 of the second transistor 194 is formed, after which the second channel and the second source or drain regions 174 based on 2D material and/or semiconductor oxide of the second transistor 194 are formed.

In these embodiments of device 100 comprising the layers 198, 200 of 2D material and/or semiconductor oxide, the forming of the first and second transistors 192, 194 and of the first and second dielectric portions 144, 154 may comprise at least:
forming, on a first surface 148 of the substrate 102, of a structure 150 comprising at least first and second stacks, each comprising portions of first and second materials that can be etched selectively over each other and arranged alternately one above the other, such that the second stack is arranged between the first stack and substrate 102, structure 150 also comprising the first dielectric portion 144 arranged between the first and second stacks, and a dummy gate 128 arranged around a portion of at least one assembly comprising at least the first and second stacks and the first dielectric portion 144;
etching, through a first part of the thickness of substrate 102 and from the first surface 148 of substrate 102, portions of the substrate not covered by structure 150;
forming of the second dielectric portions 154 covering at least side flanks of the second stack and of the first dielectric portion 144;
etching of at least a portion of dummy gate 128 and of portions of the first material of the first stack, followed by a forming of the first gate 164, and etching of portions of the second material of the first stack, followed by a deposition of at least a first layer 198 of 2D material and/or semiconductor oxide forming the first channel and the first source or drain regions 156;
removal of a second part of the thickness of substrate 102 from a second surface 170 of substrate 102 opposite to the first surface 148, such that at least one remaining portion 152 of substrate 102 is arranged against structure 150;
etching of the remaining portion 152 of substrate 102 and of portions of the first material of the second stack, followed by a forming of the second gate 186 in self-aligned manner relative to the first gate 164, and etching of the portions of the second material of the second stack, followed by a deposition of at least a second layer 200 of 2D material and/or of semiconductor oxide forming the second channel and the second source or drain regions 174.

In the various examples of embodiment, the second gate 186 of the second transistor 194 is self-aligned with the first gate 164 of the first transistor 192. This self alignment achieved through the self-alignment of the remaining portions 152 of substrate 102 with the first gate 164 of the first transistor 192, followed by the self-alignment of the second gate 186 of the second transistor 194 relative to these remaining portions 152. This self-alignment is achieved thanks to the fact a single photolithography step is implemented to define the geometry of the gate of the two transistors.

The gates of the transistors of device 100 are formed on opposite sides, that of the first transistor 192 on the front side, and that of the second transistor 194 on the back side. They can thus be formed in such a way as to be (electrically) insulated from each other.

In all examples of embodiments, the configuration of the transistors of device 100 enables to manufacture CFETs with a high density.

In the various examples, the remaining portions 152 of substrate 102 may be considered as forming dummy gates for the manufacturing of the second transistor 194.

Device 100 may comprise a greater number of transistors than in the previously-described examples.

In the various described examples, the steps implemented for the manufacturing of the first and second gates 164, 186 comprise a photolithography defining the alignment of the side flanks of the first gate 164 with the side flanks of the second gate 186.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove. For example, the precise nature of the implemented deposition and etch steps may be selected based, in particular, on the material(s) to be deposited or etched, as well as on the thicknesses of the material to be deposited or etched.

1. Device (100) with complementary field-effect transistors (192, 194), comprising at least:
a first transistor (192) of a first conductivity type comprising a first channel, first source or drain regions (156), and a first gate (164) arranged around the first channel;
a second transistor (194) of a second conductivity type, opposite to the first conductivity type, comprising a second channel, second source or drain regions (174), and a second gate (186) arranged around the second channel;
a first dielectric portion (144) arranged between the first and second gates (164, 186) and configured to electrically insulate the first and second gates (164, 186) from each other;
second dielectric portions (154), distinct from the first dielectric portion (144), each arranged between one of the first source or drain regions (156) and one of the second source or drain regions (174) and configured to electrically insulate these first and second source or drain regions (156, 174) from each other;
wherein side flanks of the first gate (164) are aligned with side flanks of the second gate (186), and wherein the first channel and the first source or drain regions (156) comprise at least one first layer (198) of 2D material and/or semiconductor oxide, and the second channel and the second source or drain regions (174) comprise at least one second layer (200) of 2D material and/or semiconductor oxide.

2. Device (100) according to claim 1, wherein the first dielectric portion (144) comprises at least one material having a chemical composition different from that of at least one material of each of the second dielectric portions (154).

3. Device (100) according to claim 1, wherein the first and second dielectric portions (144, 154) each comprise at least one low-permittivity dielectric material.

4. Device (100) according to claim 1, wherein the first gate (164) comprises at least one first metal having a work function value different from that of at least one second metal of the second gate (186).

5. Device (100) according to claim 1, wherein the first and second layers (198, 200) of 2D material and/or semiconductor oxide comprise at least one of the following materials: transition metal dichalcogenides, preferably of composition MX₂, with M selected from among molybdenum or tungsten, and X selected from among sulfur, selenium, or tellurium; IGZO; In₂O₃; IWO; ITO; IAZO; InGaZnO; InGaO; InZnO; amorphous semiconductor oxide.

6. Method of manufacturing a device (100) with complementary field-effect transistors (192, 194), comprising at least:
forming a first transistor (192) of a first conductivity type comprising a first channel, first source or drain regions (156), and a first gate (164) arranged around the first channel;
forming a second transistor (194) of a second conductivity type, opposite to the first conductivity type, comprising a second channel, second source or drain regions (174), and a second gate (186) arranged around the second channel;
forming a first dielectric portion (144) arranged between the first and second gates (164, 186) and configured to electrically insulate the first and second gates (164, 186) from each other;
forming second dielectric portions (154), distinct from the first dielectric portion (144), each arranged between one of the first source or drain regions (156) and one of the second source or drain regions (174) and configured to electrically insulate these first and second source or drain regions (156, 174) from each other;
wherein the first and second gates (164, 186) are formed in such a way that side flanks of the first gate (164) are aligned with side flanks of the second gate (186), and wherein the first channel and the first source or drain regions (156) comprise at least one first layer of 2D material and/or semiconductor oxide (198), and the second channel and the second source or drain regions (174) comprise at least one second layer of 2D material and/or semiconductor oxide (200).

7. Manufacturing method according to claim 6, wherein the steps implemented for the forming of the first and second gates (164, 186) comprise a photolithography defining the alignment of the side flanks of the first gate (164) with the side flanks of the second gate (186).

8. Method according to claim 6, wherein the forming of the first and second transistors (192, 194) and of the first and second dielectric portions (144, 154) comprises at least:
forming, on a first surface (148) of a substrate (102), of a structure (150) comprising at least first and second stacks, each comprising portions of first and second materials that can be etched selectively over each other and arranged alternately one above the other, in such a way that the second stack is arranged between the first stack and the substrate (102), the structure (150) also comprising the first dielectric portion (144) arranged between the first and second stacks, and a dummy gate (128) arranged around a portion of at least one assembly comprising at least the first and second stacks and the first dielectric portion (144);
etching, through a first part of the thickness of the substrate (102) and from the first surface (148) of the substrate (102), of portions of the substrate (102) not covered by the structure (150);
etching of at least a portion of the dummy gate (128) and portions of the first material of the first stack, followed by a forming of the first gate (164), and etching of portions of the second material of the first stack, followed by a deposition of the first layer of 2D material and/or semiconductor oxide (198);
removal of a second part of the thickness of the substrate (102) from a second surface (170) of the substrate (102) opposite to the first surface (148), such that at least a remaining portion (152) of the substrate (102) is arranged against the structure (150);
etching of the remaining portion (152) of the substrate (102) and of the portions of the first material of the second stack, followed by forming the second gate (186) in self-aligned manner relative to the first gate (164), and etching of the portions of the second material of the second stack followed by a deposition of the second layer of 2D material and/or semiconductor oxide (200).

9. Method according to claim 8, further comprising, between the etching of portions of the substrate (102) not covered by the structure (150) and the etching of at least a portion of the dummy gate (128) and of the portions of the first material of the first stack, the forming of the second dielectric portions (154) covering at least side flanks of the second stack and of the first dielectric portion (144).

10. Method according to claim 8, wherein the forming of the structure (150) comprises the forming of first and second inner spacers (142, 172).

11. Method according to claim 8, wherein the forming of the structure (150) comprises at least:
forming, on the substrate (102), an assembly comprising the first and second stacks and a dielectric layer (110) arranged between the first and second stacks;
etching the assembly in such a way that at least a remaining portion of the assembly forms a fin (124);
depositing at least one dummy gate material (128) on top of and around the fin (124);
etching the dummy gate material (128) and the fin (124), thereby forming the structure (150).

12. Method according to claim 11, wherein the forming of the stack (104) comprises a bonding of a first portion of the dielectric layer (110) previously formed on the first stack to a second portion of the dielectric layer (110) previously formed on the second stack.

13. Method according to claim 6, wherein:
the substrate (102) is of semiconductor-on-insulator type and comprises a buried dielectric layer (112) arranged between a support layer (114) and a surface semiconductor layer, and
the thickness of the buried dielectric layer (112) is equal to the first part of the thickness of the substrate (102), and
the remaining portion (152) of the substrate (102) corresponds to a portion of the buried dielectric layer (112).

14. Method according to claim 6, wherein:
the first gate (164) is formed, after which the first channel and the first source or drain regions (156) are formed, after which the second gate (186) is formed, after which the second channel and the second source or drain regions (174) are formed, or
the first gate (164) is formed, after which the first channel and the first source or drain regions (156) are formed, after which the second channel and the second source or drain regions (174) are formed, after which the second gate (186) is formed, or
the first channel and the first source or drain regions (156) are formed, after which the first gate (164) is formed, after which the second channel and the second source or drain regions (174) are formed, after which the second gate (186) is formed, or
the first channel and the first source or drain regions (156) are formed, after which the first gate (164) is formed, after which the second gate (186) is formed, after which the second channel and the second source or drain regions (174) are formed.
